(19) United States
(12) Patent Application Publication
(10) Pub. No.: US 2002/0184425 A1
(43) Pub. Date: Dec. 5, 2002

(54) Decoder expansion system

(75) Inventor: Richard M. Miller-Smith, Lingfield (GB)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/144,833

(22) Filed: Oct. 25, 2001

(30) Foreign Application Priority Data
Oct. 26, 2000 (GB) 0026207.1

(51) Int. Cl. H04N 7/16; H05K 7/10

(52) U.S. Cl. 710/301

(57) ABSTRACT

A decoder expansion system (100,110) comprises a common interface card (100), a processor (120), a common interface slot (150) and storage means (130). The common interface card (100) is inserted into a common interface slot of a decoder (not shown) to route received data under control of the processor (120) to one or both of the common interface slot (150) and the storage means (130). The system is capable of manipulating the received data and outputting a signal to the decoder via the common interface card (100) to provide additional functionality to that provided by the decoder.

The present invention relates to an expansion system that is particularly applicable for extending the capabilities of decoders such as set-top-boxes and those incorporated in integrated digital televisions.

Television programme broadcasts and interactive services transmitted over digital transmission systems such as Cable, Satellite or Radio Frequency based systems are normally multiplexed, encoded and possibly encrypted in order to be transmitted. Upon receipt, the signals must be routed through a decoder in order for the portion of the signal corresponding to a channel or service selected by a viewer to be demultiplexed and decoded before being passed on to the television for display. One form of decoder is a set-top-box that is positioned between the signal receiver (aerial, cable node, satellite dish etc.) and the television. As an alternative to an external set-top-box, the decoder may be integrated into a television set. Both types of decoder perform the same sort of functions but have different physical positions in relation to the signal receiver and the television set.

Decoders are manufactured by a number of different manufacturers, each of which may use different hardware components and configuration depending on the intended sales price of the decoder. Broadcasters and service providers have taken the opportunity offered by encrypted transmissions to charge viewers for access to individual or groups of broadcasts and services. In order to only permit selected viewers to decrypt a received broadcast or service it has become common for decoders to include a common interface (CI) slot into which a smart card personalized for that viewer that holds decryption keys and a decryption engine can be inserted to permit the decoder to decrypt the broadcast or service. Current set-top-boxes and integrated television sets are required in Europe to have at least one CI slot.

However, to balance the normal monthly charges for accessing the broadcasts and services, the price of decoders is normally subsidized and, in some cases, the features offered in decoders are limited to keep prices down. It is very uncommon to come across a decoder that has hardware components that can be extended or updated.

According to an aspect of the present invention, there is provided a decoder expansion system comprising a common interface card, a processor, a common interface slot and storage means, the common interface card being insertable into a common interface slot of a decoder so as to receive data from the decoder, wherein the processor can route the received data from the card to one, or both, of the common interface slot of the expansion system and the storage means, the system being capable of manipulating the received data and outputting a signal to the decoder via the common interface card to provide additional functionality to that provided by the decoder.

By intercepting an incoming signal at the CI slot and routing it to an expansion system the functionality and capabilities of a decoder system can be improved and/or added to without having to replace the decoder system or replace its internal hardware. For example, a storage medium could be provided that is largely transparent to the decoder system, intercepting and rerouting signals as necessary.

If the processor determines additional functionality is not needed the common interface card may be controlled to route received data back to the decoder.

The storage means may be controllable by the processor to store signals routed to it.

The storage means may be controllable by the processor to output stored signals to the common interface card for output to the decoder.

The storage means may route the output via the expansion system's common interface slot.

The storage means may be controllable by the processor to superimpose stored signals with received signals and to output a combined signal to the common interface card for output to the decoder.

The expansion system may have a plurality of CI slots.

The expansion system may comprise an expansion box housing the processor, common interface slot and the storage means, wherein the expansion box is arranged to communicate with the common interface card.

Communication between the expansion box and the common interface card may be via wireless communication means.

The expansion system may comprise a PCMCIA-type card dimensioned for insertion into the common interface slot of a decoder and housing the processor, common interface slot and the storage means.

Examples of the present invention will now be described in detail with reference to the accompanying drawings in which:

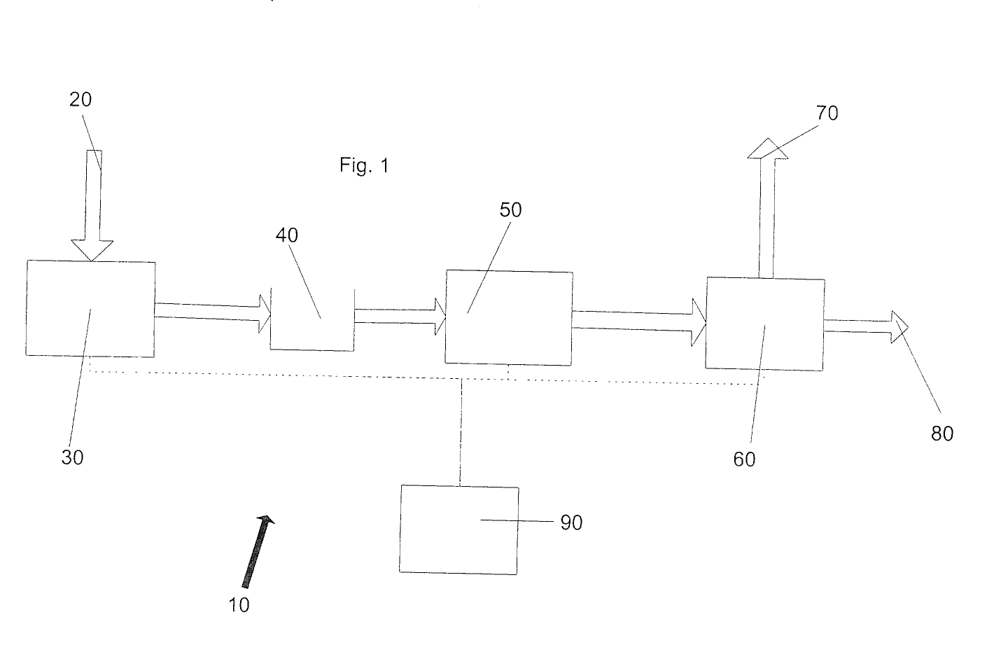

FIG. 1 is a schematic diagram of a conventional decoder; and,

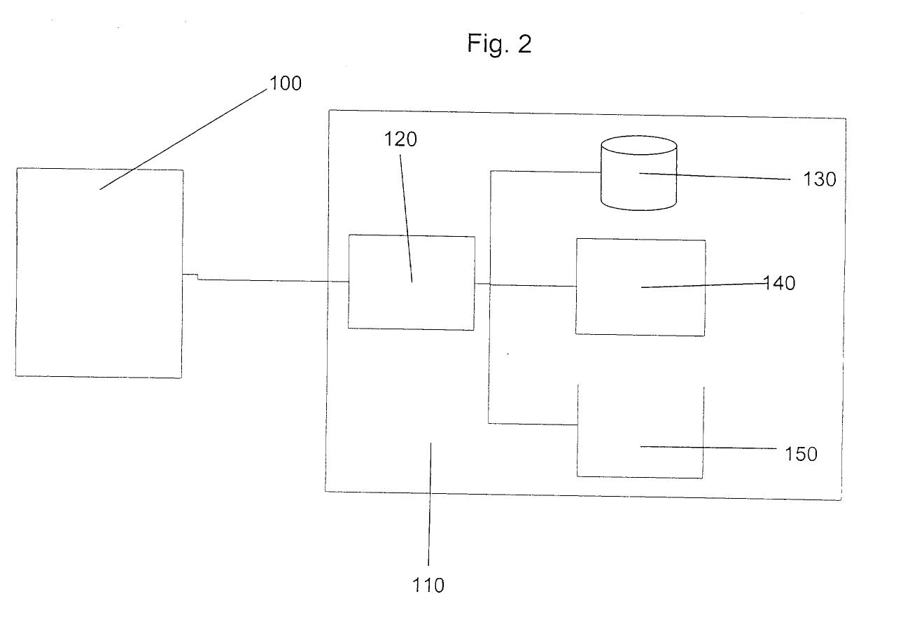

FIG. 2 is a schematic diagram of an expansion system according to an example of the present invention.

FIG. 1 is a schematic diagram of a conventional decoder 10. The decoder 10 includes an input 20 connected to a tuner 30. The tuner 30 is in turn connected to a CI slot 40 that is connected to a demultiplexer 50. The demultiplexer 50 is itself connected to a decoder 60. The decoder has outputs 70 and 80 for feeding visual and sound systems (not shown), respectively. A system processor 90 is configured to control the operation of the components 20-60 of the decoder.

In operation, a received signal is fed to the input 20 of the decoder 10. The tuner 30 passes the signal to the CI slot 40. If a smart card (not shown) is inserted in the CI slot 40, the signal is routed through the card. The system processor 90 controls the card to process and decrypt the signal. The processed signal is then passed to the demultiplexer 50 which, under the control of the system processor 90, demultiplexes the signal to retrieve the selected programme. The demultiplexed portion of the signal is then passed to the decoder 60 which decodes the signal into video and audio streams that are then passed to the relevant outputs 70, 80.

FIG. 2 is a schematic diagram of a decoder expansion system according to one example of the present invention. A CI card 100 suitable for insertion in a CI slot such as that described with reference to FIG. 1, is connected to an expansion system 110. The CI card 100 is not a smart card in the sense of that which was described with reference to FIG. 1. Instead the CI card 100 is configured to pass a received signal from the decoder 10 to the expansion system 110 and to receive signals from the expansion system 110 and pass it back to the decoder 10.

The expansion system 110 includes a processor 120, a storage medium 130, input means 140 and a CI slot 150. Signals received by the expansion system 110 are processed by the processor 120 in dependence on preprogrammed instructions. The processor 120 may also be controlled externally via the input means 140.

The expansion system 110 could be configured or controlled by the input means 140 to record signals received by the expansion system 110. The signals could then be replayed on demand at a later time. Because the CI slot of the decoder 10 is occupied by the CI card 100 that interfaces the decoder 10 to the expansion system 110, the CI slot 150 is provided to accept the viewers smart card necessary to decrypt encrypted signals. The CI slot 150 may be positioned in the signal path of the expansion system 110 before the storage medium 130. However, it is likely that it will be positioned after the storage medium 130, as shown, to prevent piracy by reproducing stored, decrypted signals. A number of CI slots 150 may be provided in the expansion system 110 to accommodate multiple smart cards for multiple service accounts or for decrypting transmissions from a number of broadcasters or service providers.

The storage medium 130 may be on hard disk, a solid state disk or some other form of memory or storage system. The input means 140 may be keys mounted on the expansion system, a receiver for a remote control or other input means. Alternatively, the control interface of the CI slot of the decoder 10 may be extended to allow commands to be passed to the processor 120 from the decoder 10. In this case, the input means 140 may not be necessary.

The expansion system 110 could be configured to operate independently of the decoder 10, intercepting the currently requested signal passed from the decoder 10 and replacing it with data from the storage medium 130.

Where a transport stream is available within the signal, it may be used to transmit data. The expansion system 110 could be configured to download data from the transport stream and store it in the storage medium 130. Under the control of the processor 120, the stored data could be inserted into the signal being output from the expansion system 110 back to the decoder 10.

The storage medium 130 may be configured to record a line broadcast so that the user could rewind or pause it. In addition, data such as TV schedules, broadcast information and associated web pages could be transmitted using the transport stream. In such cases the expansion system can act as a cache for this information which can then be accessed by the user.

Whilst the expansion system 110 described would most likely be produced as a set-top-box linked by a cable to the CI card 100 interfacing to the decoder 10, it is also possible that the whole system could be implemented as a CI card, such as a PCMCIA card. Such a card could incorporate a so called “microdrive” as the storage medium 130. Obviously such a card would only be the size of a CI card and therefore could not accommodate its own CI slot 150. In this case an external CI card slot may be provided that could communicate with the expansion system 110 via a cable connection, infra-red or other communication means.

It will be apparent to the skilled reader that the expansion system described could be used to simply and cheaply extend the capabilities of a decoder in any number of ways.

1. A decoder expansion system comprising a common interface card, a processor, a common interface slot and storage means, the common interface card being insertable into a common interface slot of a decoder so as to receive data from the decoder, wherein the processor can route the received data from the card to one, or both, of the common interface slot of the expansion system and the storage means, the system being capable of manipulating the received data and outputting a signal to the decoder via the common interface card to provide additional functionality to that provided by the decoder.

2. A decoder expansion system according to claim 1, in which if the processor determines additional functionality is not needed the common interface card is controlled to route received data back to the decoder.

3. A decoder expansion system according to claim 1, in which the storage means is controllable by the processor to store signals routed to it.

4. A decoder expansion system according to claim 1, in which the storage means is controllable by the processor to output stored signals to the common interface card for output to the decoder.

5. A decoder expansion system according to claim 4, in which the storage means routes the output via the expansion system's common interface slot.

6. A decoder expansion system according to claim 3, in which the storage means is controllable by the processor to superimpose stored signals with received signals and to output a combined signal to the common interface card for output to the decoder.

7. A decoder expansion system according to claim 1, comprising a plurality of common interface slots.

8. A decoder expansion system according to claim 1, comprising an expansion box housing the processor, common interface slot and the storage means, wherein the expansion box is arranged to communicate with the common interface card.

9. A decoder expansion system according to claim 8, in which communication between the expansion box and the common interface card is via wireless communication means.

10. A decoder expansion system according to claim 1, comprising a PCMCIA-type card dimensioned for insertion into the common interface slot of a decoder and housing the processor, common interface slot and the storage means.
